(19) United States
(12) Patent Application Publication
(10) Pub. No.: US 2026/0231360 A1
(43) Pub. Date: Aug. 6, 2026

(54) STATOR ASSEMBLY FOR MICRO-AXIAL PUMP

(71) Applicant: HEWLETT PACKARD ENTERPRISE DEVELOPMENT LP, Spring, TX (US)

(72) Inventors: Laura Sofia Lester, Spring, TX (US); John P. Franz, Tomball, TX (US); Ernesto Juan Ferrer, Aguadilla (PR)

(21) Appl. No.: 19/042,130

(22) Filed: Jan. 31, 2025

(51) Int. Cl. H05K 7/20; F04D 3/00; F04D 13/06; H02K 16/04

(52) U.S. Cl. CPC H05K 7/20272; F04D 3/00; F04D 13/06; H02K 16/04; H05K 7/20254; H05K 7/20772

(57) ABSTRACT

An axial pump for delivering liquid coolant to cool an electronic device comprises a conduit defining a liquid flow path and an impeller/rotor disposed in the conduit. A stator is disposed outside the conduit to drive rotation of the impeller/rotor about an axis of rotation extending parallel to the liquid flow path. The stator comprises a first stator subassembly and a second stator subassembly disposed on diametrically opposite lateral sides of the conduit. Each stator subassembly comprises: a frame with a bobbin column, a winding wound around the bobbin column, a top stator core portion inserted into a bore of the bobbin column via a top opening in the bore; and a bottom stator core portion inserted into the bore of the bobbin column via a bottom opening in the bore.

### INTRODUCTION

Some information processing systems utilize liquid cooling techniques to remove heat from the system. In these systems, a liquid coolant is circulated in a loop through the information processing devices (e.g., servers, networking devices, etc.) of the system, and heat generating components thereof (e.g., processors) are thermally coupled (e.g., via cold plates) to the liquid coolant so that the liquid coolant absorbs heat from these components. As the now-heated coolant exits the information processing devices, it carries the heat to a cooling device (such as a heat exchanger) which cools the liquid back to a desired operating temperature, whereupon the cooled liquid is circulated through the loop once again, extracting more heat from the information processing devices. Such a liquid cooling loop uses one or more pumps to drive the circulation of the liquid through the loop. Often, these pumps are disposed in a so-called coolant distribution unit (CDU) that provides a centralized pumping unit to circulates the liquid collectively through multiple information processing devices (e.g., an entire rack, or multiple racks, of such devices). These pumps are usually very large, with the CDU often taking up a substantial portion of a rack, or in some cases a full rack.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic diagram illustrating an example pump.

FIG. 2 is a perspective view of another example pump.

FIG. 3 is an exploded view of the pump of FIG. 2.

FIG. 4 is an exploded perspective view of an impeller chamber subassembly of the pump of FIG. 2, including a perspective sectional view of a portion of the impeller chamber subassembly with the section taken along the plane 4-4 indicated in FIG. 2.

FIG. 5 is a cross-section of the pump of FIG. 2, with the section taken along the plane 4-4 indicated in FIG. 2.

FIG. 6 is a cross-section of the pump of FIG. 2, with the section taken along the plane 6-6 indicated in FIG. 2.

FIG. 7 is a perspective view of a frame of a stator subassembly of the pump of FIG. 2 in isolation.

FIG. 8 is another perspective view of the frame of FIG. 7.

FIG. 9 is a perspective view of a stator subassembly of the pump of FIG. 2 in a first state of assembly.

FIG. 10 is a perspective view of the stator subassembly of FIG. 9 in a second state of assembly.

FIG. 11 is a perspective view of the stator subassembly of FIG. 9 in a third state of assembly.

FIG. 12 is a perspective view of the stator subassembly of FIG. 9 in a fourth state of assembly.

FIG. 13 is a schematic diagram of an information processing system with a pump.

### DETAILED DESCRIPTION

In some cases, it may be desired to utilize relatively small pumps in liquid cooling loops, rather than the commonly used large CDU pumps. One advantage of using smaller pumps for liquid cooling information processing systems is that the smaller pumps can be more efficient than the larger pumps, in terms of the amount of liquid they can move per unit of energy spent. The smaller pumps can also fit in places that the large pumps will not, which opens opportunities for system designers to arrange their systems in new and potentially more efficient ways which would not have otherwise been possible. For example, smaller pumps can allow for a distributed pumping architecture to be utilized, in which each information processing device is provided with one or more small pumps localized to the device (e.g., disposed within, or adjacent to, the chassis of the device) to control the circulation of fluid locally through that device in an individualized manner, rather than using a single large centralized pumping unit to control the flow of fluid collectively through all the devices in a rack or multiple racks. This distributed approach can improve efficiency and performance of the liquid cooling loop, potentially reducing power usage and noise while also delivering more coolant flow (and hence better cooling). In addition, this may also facilitate greater modularity and scalability of the system, as the pumping capacity of the system naturally scales along with the demand for cooling, since each new device added to the system brings its own pump(s) with it.

While having smaller pumps can in theory be advantageous, realizing these advantages can be challenging with existing pump technologies. Many existing pumps that can produce the needed levels of pressure and liquid flow rates for liquid cooling an information processing device are simply too large, or are too awkwardly shaped, to fit well within the densely packed environment of an information processing device. Other pumps (such as artificial heart pumps) may be small enough to fit in a space-constrained information processing system, but these generally have inadequate pumping characteristics (e.g., insufficient pressure, insufficient flow rates, poor efficiency, etc.) for the liquid cooling context. In other words, it is challenging to find pumps which both have a suitable small form factor and which have desired pumping characteristics.

Thus, to meet this unique combination of challenges, specialized pumps are being developed, such as the micro-axial pumps described in U.S. Pat. No. 11,015,608 B2, the contents of which are incorporated herein by reference in their entirety. An axial pump has an impeller (the part that moves within the liquid to drive the flow) that spins along an axis that is coaxial with a flow direction of the liquid, in contrast to centrifugal pumps which have impellers that spin along an axis transverse to the flow direction of the liquid. In addition, in certain micro-axial pumps such as those disclosed in U.S. Pat. No. 11,015,608B2 , the rotor (the part which is magnetically driven to rotate) is attached directly to the impeller forming a rotor/impeller assembly which is entirely disposed within the fluid channel, as opposed to having a rotor sitting outside of the fluid channel with a shaft piercing through a wall of the channel and connecting the rotor to the impeller. A stator sitting outside the fluid channel generates magnetic fields in response to receiving electrical driving current, these magnetic fields interact with permanent magnets in the rotor to generate a torque on the impeller/rotor assembly which causes it to spin, and blades extending along the exterior of the spinning impeller push liquid through the pump. The axial arrangement, together with various other improvements, allows for the micro-axial pumps to have a form factor which is both extremely small and conveniently shaped (e.g., rectangular in cross-section), while still providing the same or better effectiveness and efficiency as larger pumps. For example, some micro-axial pumps under development may be similar in size and shape to a deck of cards while being capable of providing flow rates of such as 4 GPM at 4PSID, 2 GPM at 11.5 PSID, or 1 GPM at 13.9 PSID (PSID refers to a pressure drop in pounds per square inch).

However, the size and form factor of such micro-axial pumps can pose a variety of technical challenges. To allow the pump to have a rectangular profile and low height, some micro-axial pumps adopt a stator design in which the stator has two halves which are disposed on diametrically opposite lateral sides of the conduit, with each half of the stator having a wire winding wound around a stator core (“winding,” when used as a noun herein, refers to the overall coiled structure formed by a wire which has been wound). The stator core is shaped generally like “⊏” (e.g., like a U rotated 90 degrees), with a vertical base around which the windings are wound and a pair of stator teeth protruding horizontally from the top and bottom of the base toward the conduit. Because the stator teeth are disposed outside the liquid conduit and the rotor is disposed inside the conduit, a relatively large air gap is present therebetween, with the air gap spanning a wall of the conduit, a wall of the impeller, and the space between these two walls through which the liquid flows. Because of this large air gap, the stator teeth may need to be relatively large in order to allow for adequate flux linkage between the stator teeth and rotor. Furthermore, in some axial pumps, to reduce the height dimension of the pump, stator teeth are not positioned in the spaces directly above and below the conduit, and to compensate for this, the remaining stator teeth may need to be even larger.

However, relatively large stator teeth can make it very difficult to wind the wire around the base of the stator core using existing winding techniques. As the teeth become larger the distal ends thereof start to close off the open end of the U-shaped stator core. For example, a portion of the top stator tooth may protrude downward while a portion of the bottom stator tooth may protrude upward, and as these protrusions increase in size the opening therebetween becomes smaller. To wind the wires around the base of the stator core requires passing them through this opening, and therefore any reduction in size of this opening makes the winding process harder. While it is possible to fit wires through the opening, the obstructions posed by the stator teeth makes it difficult or even impossible to achieve good fill factors for the windings using traditional winding machines.

To address these and other challenges, disclosed herein are example stators configured to enable easy winding of wires despite having large stator teeth. In particular, the stator comprises a support frame to support a stator core in the assembled pump, and this support frame comprises a bobbin column around which a wire can be wound while the stator core is absent. After the winding, the stator core is then inserted into a hollow bore of the bobbin column such that the base of the stator core is surrounded by the wire winding. Because the wire is wound while the stator core is not yet present, the large stator teeth of the stator core do not interfere with the winding. Thus, the wires can be easily wound with a good fill factor using traditional winding machines.

More specifically, in some examples the stator is formed from two separate stator cores which are part of two stator subassemblies disposed on diametrically opposite lateral sides of the conduit. Each stator subassembly comprises a stator frame, a stator core supported by the stator frame, and a wire wound around the stator core and the stator frame. The stator frame may also form part of the housing of the pump. The stator frame is configured to guide and support the wires as they are wound around the bobbin column such that they produce a wire winding with a suitable shape. The bobbin column may be hollow, with a central bore extending vertically therethrough with openings on top and bottom sides of the bobbin column. The wire is wound circumferentially around the exterior of the bobbin column such that a central axis of the winding is approximately coaxial with the central axis of the bore of the bobbin column.

Further, each stator core is split into top and bottom core portions, with the split occurring in the base of the core such that each of the top and bottom core portions comprises part of the base (“a base portion”) and one of the stator teeth extending horizontally from the base portion. In some examples, the split is made near the middle of the base such that each base portion comprises about half of the base. This split design of the stator core allows the stator core to be inserted into the center of the already-formed wire winding, rather than forming the winding on the stator core. Specifically, with the wire winding already formed on the bobbin column, the base portion of the top core portion can be aligned with and inserted into the top opening of the central bore of the bobbin column and the base portion of the bottom core portion can be aligned with and inserted into the bottom opening of the central bore of the bobbin column. Then the top core portion may be moved downward and the bottom core portion moved upward to advance their respective base portions through the central bore of the bobbin column until they meet near the middle of the bobbin column. Because the wire winding has already been wound around the outside of the bobbin column prior to insertion of the stator core portions, as the base portions of the top and bottom core portions are inserted into and advanced through the central bore of the bobbin column, they are simultaneously being inserted in and advanced through a center of the windings. The bobbin column maintains the shape of the windings during this process and prevents the stator cores from inadvertently colliding with and dislodging coils of the winding while the stator cores are being inserted into the center of the winding. Once the top and bottom core portions have been inserted into the bobbin column, they may be secured to the stator frame, e.g., by friction fit, adhesives, and/or other fastening techniques. In this state, the top and bottom core portions may together form a stator core with the wire winding being wound around a base of this stator core. The resulting stator subassembly formed from the split stator core portions and the separately wound wire winding may be similar in function to a hypothetical comparative stator subassembly in which the stator core has the same overall shape but has a unitary (non-split) design, except that the example stators disclosed herein may benefit from an easier wire winding process (making them less expensive to manufacture) and/or may have better wire fill factors (which can result in better pump performance).

Turning now to the figures, various devices, systems, and methods in accordance with nonlimiting aspects of the present disclosure will be described.

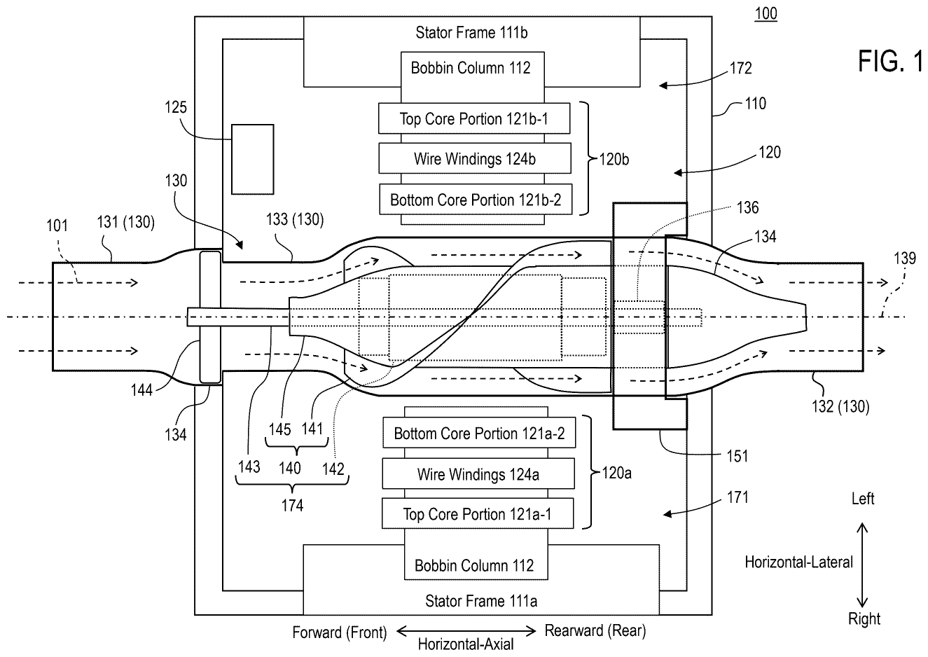

FIG. 1 is a schematic diagram conceptually illustrating a pump 100. FIG. 1 shows the pump 100 from a perspective above the pump and illustrates functional and some general positional relationships between components, as described below, but the diagram is schematic in nature and is not intended to illustrate specific shapes, dimensions, or other structural details accurately or to scale. It should be understood that implementations of the pump 100 can vary from one another in various aspects. Some implementations of the pump 100 may have different numbers and arrangements of the illustrated components. Some implementations of the pump 100 may include other parts that are not illustrated in FIG. 1. Some implementations of the pump 100 may omit one or more of the parts that are illustrated in FIG. 1.

As shown in FIG. 1, the pump 100 comprises a housing 110, a stator 120 (also “motor stator 120”), control circuitry 125, a conduit 130 defining a liquid flow path 101, and an impeller/rotor sub-assembly 174 comprising an impeller 140, a rotor 142, and a shaft 143. The housing 110 and conduit 130 are shown as transparent to allow visibility of the other components. In addition, some parts (or portions of parts) which are covered by (e.g., contained within) other parts are shown in dotted lines; this is done to make it easier to visually distinguish the covered parts from the covering parts. The components of the pump 100 will be described in greater detail below.

The housing 110 comprises one or more walls or other support structures that support and at least partially enclose or house some of the other components of the pump 100. The housing 110 may be a single part or made from multiple parts assembled together. In some examples, the parts of the housing 110 may also be coupled to and/or form an integral part of the other parts of the pump 100. For example, portions of the conduit 130 may also form parts of the housing 110.

The conduit 130 comprises walls that partially enclose a volume and define the liquid flow path 101 through that volume, with the liquid flow path 101 being the path along which liquid coolant (e.g., water or other coolants) flows as it traverses the pump 100. The conduit 130 comprises a pump inlet portion 131 (also “inlet 131”) having a first opening into the enclosed volume of the conduit 130, a pump outlet portion 132 (also “outlet 132”) having a second opening into the enclosed volume of the conduit 130, and an impeller chamber portion 133 between the other two portions 131/132. The impeller chamber portion 133 houses the impeller 140 and is fluidically coupled to the inlet 131 and outlet 132. The pump inlet portion 131 and pump outlet portion 132 may comprise structures for fluidically coupling the pump with coolant lines of a liquid cooling loop, such as hose barbs, fittings, quick connect couplings, and/or other liquid coupling mechanisms as would be familiar to those of ordinary skill in the art. The conduit 130 may be liquid tight, sealing the interior volume from an exterior environment, other than at openings in the inlet 131 and outlet 132 that allow the enclosed interior volume to be fluidically coupled to the exterior environment (e.g., to coolant lines of a liquid cooling loop). In some examples, the inlet 131 and outlet 132 may extend outside of the housing 110 of the pump 100. In some examples, the impeller chamber portion 133 is contained within the housing 110.

The conduit 130 has a central longitudinal axis. This axis is coaxial with various other axes of other parts of the pump 100, including a rotational axis of the rotor 142, a rotational axis of the impeller 140 (described below), and a central longitudinal axis of a shaft 143, and therefore all of these axes are depicted in FIG. 1 by the same axis 139. Accordingly, all of these co-axial axes may hereinafter be referred to interchangeably as the axis 139. Liquid flowing through the conduit 130 flows, as whole, along directions parallel to the axis 139, as indicated by the dashed arrows representing the flow path 101 in FIG. 1. Note that the liquid may also spiral circumferentially around the axis 139 (in addition to moving axially) while traversing certain portions of the flow path 101 (e.g., while passing the impeller 140), but the bulk or average motion of the liquid as a whole in traversing the conduit 130 is along directions parallel to the axis 139. The liquid flow path 101 is shown in FIG. 1 to illustrate how the pump 100 is configured to flow liquid when deployed, but note that the liquid is not necessarily part of the pump 100 and is not necessarily present in all states of the pump 100. For example, prior to being deployed in a liquid cooling loop, there might be no liquid in the pump 100.

As mentioned above, the impeller/rotor sub-assembly 174 comprises an impeller 140 and a rotor 142 attached together and disposed within the conduit 130. The impeller/rotor sub-assembly 174 also comprises a shaft 143 to which rotor 142 is rotatably attached such that the rotor 142, and the impeller 140 coupled thereto, can rotate about the shaft 143. A rotation axis of the rotor 142, a rotation axis of the impeller 140, a longitudinal axis of the shaft 143, and a longitudinal axis of the conduit 130, are all coaxial, as mentioned above. The shaft 143 is fixedly attached to the housing 110, and thus when the rotor 142 and impeller 140 rotate about the shaft 143, they are also rotating relative to the housing 110. The impeller 140 and the rotor 142 will be described in greater detail in turn below.

The impeller 140 is housed within the conduit 130, specifically in the impeller chamber 133 thereof. The impeller 140 is configured to, when rotated about the axis 139, drive liquid to flow along the flow path 101 through the conduit 130. The impeller 140 comprises an impeller body 145 and blades 141 that protrude radially from and spiral along/around the impeller body 145. References to the blades 141 spiraling along or around the impeller body 145 mean that the blades 145 extend along paths that axially traverse the impeller body 145 while simultaneously circling circumferentially around the impeller body 145 through at least portions of the path; for example, the paths could be helical. The blades 141 are configured to force the liquid axially along the flow path 101 through the conduit 130 as the impeller 140 rotates.

The impeller body 145 is hollow (i.e., has an internal bore therethrough) and the rotor 142 is at least partially contained within the hollow interior of the impeller 140. Specifically, the impeller body 145 may have a shape roughly of a hollow cylinder with openings at both ends and with one end being tapered/rounded. The shaft 143 also extends through the internal bore of the impeller body 145.

In some examples, the impeller body 145 and the impeller blades 141 are integrally connected, meaning they are formed together as two parts of the same monolithic body. The impeller body 145 may be formed from any solid material which can be formed into the desired shape. For example, the impeller body 145 may be formed from various plastics, which can be formed into the desired shape by injection molding, additive manufacturing (e.g., 3D printing), or other techniques. As another example, the impeller body 145 may be formed from various metals, which can be formed into the desired shape by casting, additive manufacturing (e.g., 3D printing), or other techniques.

The rotor 142 comprises magnetic portions (e.g., permanent magnets) and bearings, which are coupled together such that the bearings support the magnetic portions. The bearings are in turn rotatably coupled to the shaft 143 such that the rotor 142 can rotate about the shaft 143. Specifically, the magnetic portions of the rotor 142 are arranged to interact with magnetic fields generated by the stator 120 (which will be described below) to produce rotation of the rotor 142. The rotor 142 is disposed within and attached to the impeller body 145 (e.g., by press-fitting, adhesive, or other means), such that the rotation of the rotor 142 causing the impeller 140 attached thereto to also rotate. Thus, the rotor 142 and the stator 120 may together form an electromagnetic motor. The magnetic portions may comprise permanent magnets and/or magnetically attractable (e.g., ferromagnetic) materials (e.g., iron, steel, etc.) which are capable of interacting with (e.g., being attracted or repelled by) the generated magnetic fields. In some examples, the magnetic portions comprise multiple permanent magnets which are distributed circumferentially around the axis 139 and arranged with alternating polarities.

As shown in FIG. 1, the shaft 143 is secured to the conduit 130 and housing 110 via a front support 144 and a rear support 151. The front support 144 engages and holds a front portion of the shaft 143 and is coupled to the walls of the conduit 130. The rear support 151 engages and holds a rear portion of the shaft 143 and is also coupled to the walls of the conduit 130. Front and rear are used herein in relation to the orientation of the pump 100 illustrated in FIG. 1, with the inlet side being the “front” side and the outlet side being the “rear” side. However, these terms are meant merely to aid understanding and are not limiting. In particular, in some examples of the pump 100, the supports 144 and 151 could be reversed in orientation, with the support 144 being nearer the outlet 132 and the support 151 being nearer the inlet 131, in which case the terms “front” and “rear” as used herein would be reversed in relation to these components.

In some examples, the pump 100 further comprises an adjustment mechanism 136. The adjustment mechanism 136 couples the shaft 143 to the rear support 151. The adjustment mechanism 136 is actuatable, and when actuated changes the position of the shaft 143 relative to the rear support 151, and hence also relative to the impeller chamber 133. More specifically, the adjustment mechanism 136 is configured to cause translation along the rotation axis 139 of the rear end of the shaft 143 relative to the rear support 151, which in turn causes translation of the front end of the shaft 143 relative to the front support 144. Because the shaft 143 is coupled to the rotor 132 and the rotor 132 is coupled to the impeller 140, when the shaft 143 is translated along the axis 139 this also causes the impeller 140 to be translated along the axis 139 relative to conduit 130. Adjusting the position of the impeller 140 in this manner can change the clearance between the blades 141 and the walls of the conduit 130, particularly near the front end of the impeller 140. This can allow for smaller clearances to be obtained between the blades 141 and conduit 130, which improves performance, without requiring high precision in the parts which would inordinately increase costs. The adjustment mechanism 136 may include, in some examples, any of the adjustment mechanisms described in U.S. patent application Ser. No. 17/977,200 entitled “AXIAL PUMP WITH ADJUSTABLE IMPELLER” and filed on Oct. 31 2022, the entire contents of which is incorporated herein by reference.

The stator 120 is configured to receive electrical power from the control circuitry 125 and in response generate alternating magnetic fields that interact with the rotor 142 of the impeller/rotor sub-assembly 174 to cause the rotor 142 (and hence the impeller 140 coupled thereto) to rotate about a rotation axis thereof, depicted in FIG. 1 as axis 139. As shown in FIG. 1, the stator 120 comprises a first stator portion 120a and a second stator portion 120b arranged on diametrically opposite lateral sides of the conduit 130. Each of these stator portions 120a/120b comprises a stator core and wire windings 124a/124b wound around the stator core. The windings 124a/124b generate magnetic fields in response to electric current flowing therethrough. The stator cores include stator teeth which extend and shape the generated magnetic fields in the desired pattern around the conduit 130, such that the magnetic fields can drive rotation of the rotor 142. The stator cores are made from magnetically susceptible materials, which in some examples may be arranged in a laminated stack.

The first stator portion 120a is coupled to and supported by a corresponding stator frame 111a, which together form a first stator subassembly 171. The second stator portion 120b is coupled to and supported by a corresponding stator frame 111b, which together form a second stator subassembly 172. The stator core of each of the stator portions 120a/120b has a split design, including a top core portion and a bottom core portion which are (at least initially) physically distinct from one another. More specifically, the stator core of the stator portion 120a comprises a top core portion 121a-1 and a bottom core portion 121a-2. Similarly, the stator core of the stator portion 120b comprises a top core portion 121b-1 and a bottom core portion 121b-2. These top and bottom stator core portions 121a-1, 121a-2, 121b-1, and 121b-2 may also be referred to collectively herein as “core portions 121.” Each of the core portions 121 may comprise multiple thin core layers, each formed of a magnetically susceptible material, which are laminated together with a stacking direction being parallel to the rotation axis 139. In cross-section, each of the core portions 121 comprises a vertically extending base portion, around which the wire windings 124a/124b are wound, and a stator tooth extending horizontally from the base portion towards the conduit 130. When the top and bottom stator core portions 121a-1 and 121a-2 are both installed in the subassembly 171, their respective base portions are aligned vertically with and abut one another and their respective stator teeth extend generally parallel to one another, together forming a stator core shaped generally like “⊏”. The top and bottom stator core portions 121b-1 and 121b-2 are both installed in the subassembly 172 in the subassembly 172 in a similar manner forming a similar shape. The two stator cores are then arranged on diametrically opposite lateral sides of the conduit 133 with their open ends facing each other.

Thus, in some examples, the two stator cores together form a combined stator core having a cross-sectional profile which is rectangular in shape. As used herein, a rectangular cross-sectional profile means that, in a cross-section perpendicular to the central axis of the pump, a rectangle can be drawn around the combined stator core in which: (a) the top edges of both of the stator cores correspond to (e.g., align with and follow/trace) a top edge of the rectangle, (b) the bottom edges of both of the stator cores correspond to a bottom edge of the rectangle, (c) the outer side edge of one stator is corresponds to a first side edge of the rectangle, and (d) the outer side edge of the other stator core corresponds to a second side edge of the rectangle.

Note that the above definition of “rectangular cross-sectional profile” allows for there to be gaps between the two top edges of the stator cores and the two bottom edges of the stator cores, as the stator cores are not necessarily in contact with one another and do not necessarily form a single unitary body. More specifically, references to the top edges of the stator cores corresponding to the top edge of the rectangle should not be misunderstood as meaning that the top edges of the stator cores form a continuous line extending fully across the width of the top edge of the hypothetical rectangle, but instead these references should be understood as meaning that that the top edges of the stator cores correspond to two separate portions of the top edge of the rectangle which may be separated by a gap. In other words, the top edges of the stator cores are disposed side-by-side along the top edge of the rectangle with a small gap therebetween near the centerline of the pump. The same is true for the bottom edges.

In addition, the above definition of “rectangular cross-sectional profile” allows for the profile of the stator core to have small deviations from a perfectly rectangular shape, such as having rounded corners, notches/grooves in the edges, chamfers/fillets, etc., so long as the top, bottom, and side edges thereof correspond to the edges of the hypothetical rectangle as defined above. In some examples, an edge of a stator core “correspond to” an edge of the rectangle if the respective edge of the stator core is aligned with and follows (traces) the corresponding edge of the rectangle along at least 70% of the length of the respective edge of the stator core. In some examples, an edge of a stator core “correspond to” an edge of the rectangle if the respective edge of the stator core is within 1 mm of the corresponding edge of the rectangle along at least 70% of the length of the respective edge of the stator core.

In some examples, the cross-sectional profile of the stator core is elongated, meaning the aspect ratio thereof is A:1, wherein A is a number greater than 1. In some examples, the aspect ratio is 1.5:1 or greater. In some examples, the aspect ratio is 2:1 or greater. The aspect ratio refers to the ratio of the width in the horizontal/lateral dimension to the height in the vertical dimension.

As mentioned, each stator subassembly 171/172 comprises a stator frame 111a or 111b. The stator frames 111a and 111b form part of the housing 110, as well as forming a support structure to support the stator portions 120a and 120b. The stator frame 111a includes, among other things, a bobbin column 112 around which the wire windings 124a may be wound before the stator core portions 121a-1 and 121a-2 are assembled to the stator frame 111a. Likewise, the stator frame 111b includes, among other things, a bobbin column 112 around which the wire windings 124b may be wound before the stator core portions 121b-1 and 121b-2 are assembled to the stator frame 111b. Each bobbin column 112 may be hollow, with a central bore extending vertically therethrough with openings on top and bottom sides of the bobbin column 112. The wire of the wire winding 124a is wound circumferentially around the exterior of one of the bobbin columns 112 such that a central axis of the winding is approximately coaxial with the central axis of the bore of the bobbin column 112, and the wire of the winding 124b is similarly wound around the other bobbin column 112. The stator frames 111a/112b guide and support the wires as they are wound such that they produce the windings 124a/124b with suitable shapes.

As mentioned above, each stator core is split into top and bottom core portions 121, with the split occurring in the base of the core such that each of the top and bottom core portions 121 comprises part of the base (“a base portion”) and one of the stator teeth extending horizontally from the base portion. In some examples, the split is made near the middle of the base such that each base portion comprises about half of the base. This split design of the stator core allows the stator core to be inserted into the center of the already-formed wire winding 124a/124b, rather than forming the winding 124a/124b on the stator core.

Specifically, with the wire winding 124a already formed on the bobbin column 112 of the stator frame 111a, the base portion of the top core portion 121a-1 can be aligned with and inserted into the top opening of the central bore of the bobbin column 112 and the base portion of the bottom core portion 121a-2 can be aligned with and inserted into the bottom opening of the central bore of the bobbin column 112. Then the top core portion 121a-1 may be moved downward and the bottom core portion 121a-2 moved upward to advance their respective base portions through the central bore of the bobbin column 112 until they meet near the middle of the bobbin column 112. Because the wire winding 124a has already been wound around the outside of the bobbin column 112 prior to insertion of the stator core portions 121a-1 and 121a-2, as the base portions of the top and bottom core portions 121a-1 and 121a-2 are inserted into and advanced through the central bore of the bobbin column 112, they are simultaneously being inserted in and advanced through a center of the winding 124a. The bobbin column 112 maintains the shape of the winding 124a during this process and prevents the core portions 121a-1 and 121a-2 from inadvertently colliding with and dislodging coils of the winding 124a while the core portions 121a-1 and 121a-2 are being inserted into the center of the winding 124. Once the top and bottom core portions 121a-1 and 121a-2 have been inserted into the bobbin column 112, they may be secured to the stator frame 111a, e.g., by friction fit, adhesives, and/or other fastening techniques, thereby forming the first stator subassembly 171. In this state, the top and bottom core portions 121a-1 and 121a-2 may act like a single unitary stator core, which together with the wire winding 124a forms stator portion 120a.

The second stator assembly 172 is assembled in a similar manner as described above with respect to first stator assembly 171, with the top and bottom core portion 121b-1 and 121b-2 being inserted into the bobbin column 112 of the stator frame 111b in a state in which the wire winding 124b have already been wound around the bobbin column 112.

Once the first and second stator subassemblies 171 and 172 have been assembled, they may be disposed on opposite lateral sides of the impeller chamber 133, with each being oriented with the distal ends of their stator teeth adjacent to the impeller chamber 133 and the bobbin column 112 and wire winding 124a/124b thereof being located farther from the impeller chamber 133. The stator frames 111a and 111b may then be attached to other portions of the housing 110, which in turn may be attached to the impeller chamber 133, thus securing the first and second stator subassemblies 171 and 172 to the impeller chamber 133.

The control circuitry 125 is configured to control operations of the pump 100. In some examples the control circuitry 125 comprises a printed circuit assembly (PCA) with various electronic components formed therein and/or mounted thereon, and/or additional components external to the PCA. In some examples the control circuitry 125 includes logic to drive operations of the pump 100. For example, control circuitry 125 may include a microcontroller. As another example, the control circuitry 125 may include discrete logic circuits (digital or analog), in addition to or instead of a microcontroller. The control circuitry 125 may also include sensors, such as temperature sensors, electrical power usage sensors, moisture sensors (e.g., for leak detection), magnetic field (e.g., Hall effect) sensors, or other sensors. The control circuitry 125 may also include power delivery components, such as transistors or other switches (e.g., relays), capacitors, diodes, etc. In some examples, the control circuitry 125 may include communications components for communicating with outside devices such as a system controller, baseboard management controller (BMC), rack controller, etc., for example via the cables (not illustrated) coupled to the pump 100 and/or wirelessly (via, e.g., Bluetooth, WiFi, etc.). The control circuitry 125 may be electrically coupled to the stator 120 to provide electrical signals thereto to drive the operation of the stator 120. The control circuitry 125 may be coupled to an outside power source and/or an outside controller via wires or cables (not illustrated).

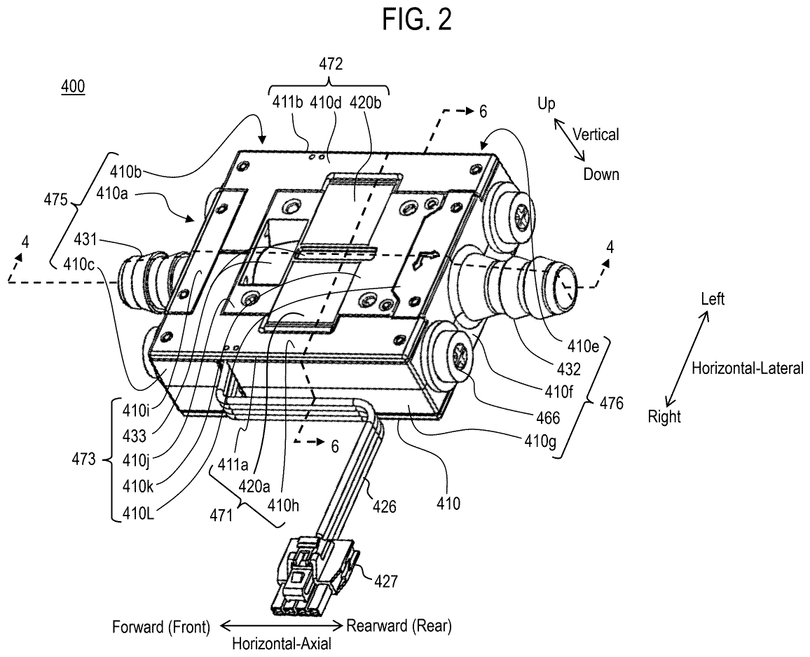

Turning now to FIGS. 2-12, another example pump will be described, in the form of pump 400. The pump 400 is an example implementation of the pump 100 described above. Thus, some components of the pump 400 are similar to (e.g., example implementations or configuration of) corresponding components already described above, and thus the descriptions of the components of the pump 100 above are applicable to the similar components of the pump 400, and duplicative descriptions of certain aspects of the pump 400 may thus be omitted. Corresponding components may be referred to using reference numbers having the same last two digits, such as 110 and 410. It should be understood that the pump 400 is but one possible implementation of the pump 100, and the pump 100 is not limited to the pump 400. Similarly, the individual components of the pump 400 are examples of the corresponding individual components of the pump 100, but the individual components of the pump 100 are not limited to the corresponding components of the pump 400.

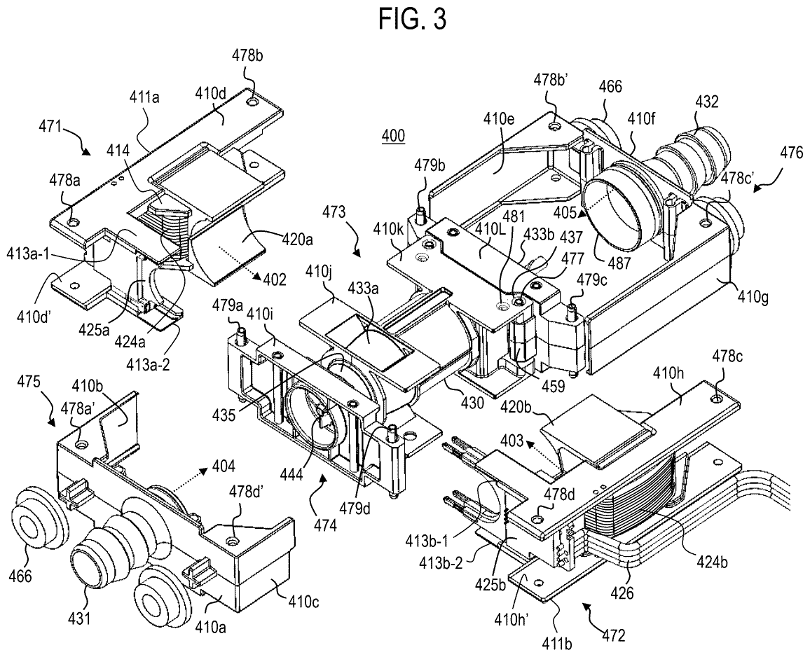

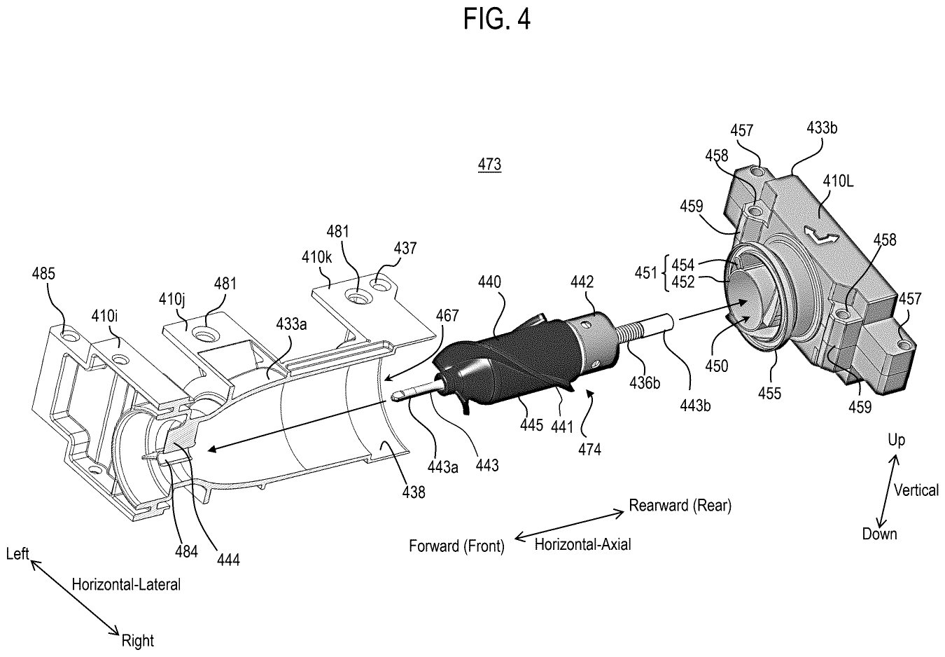

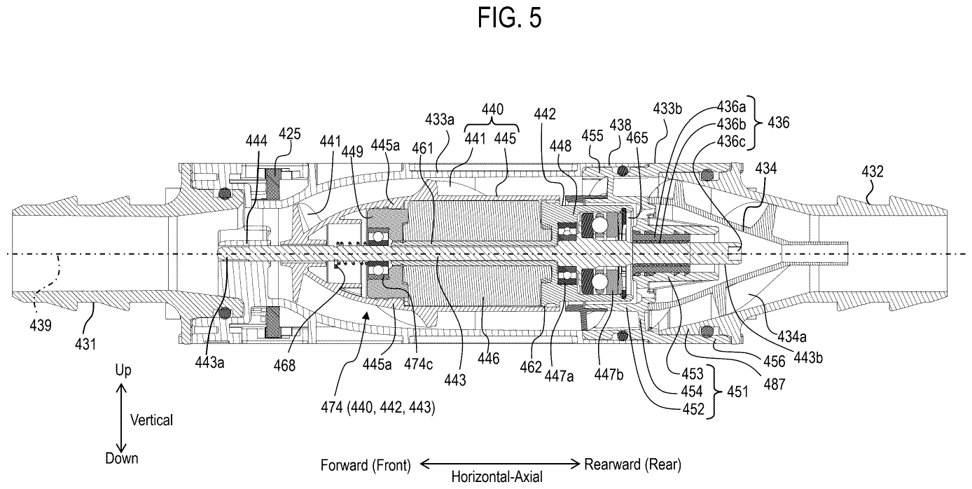

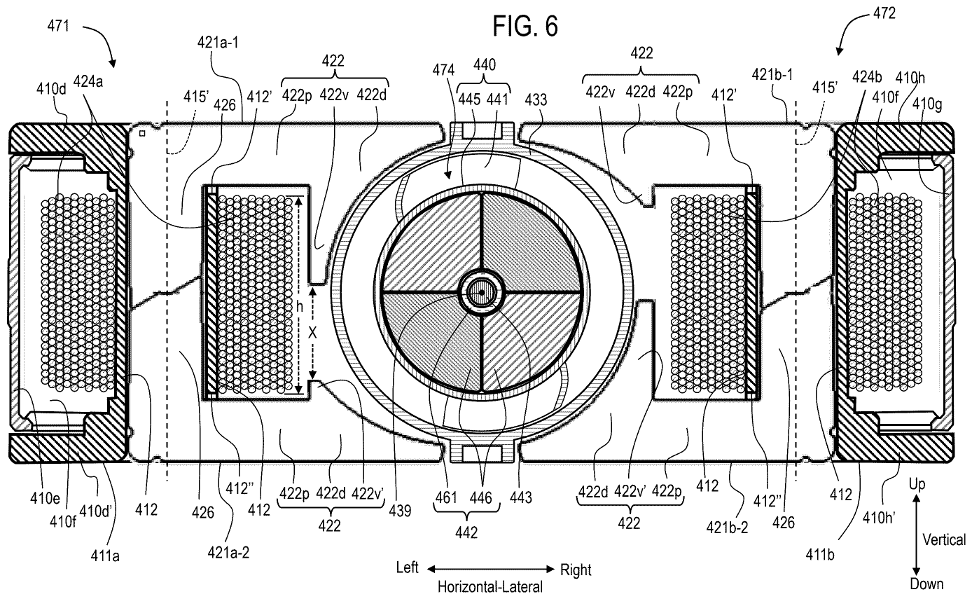

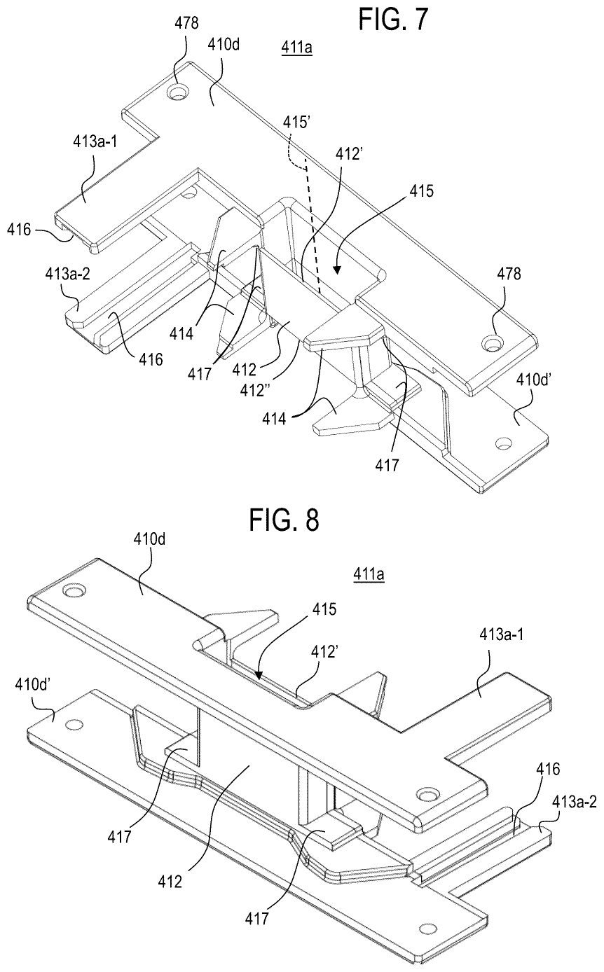

FIG. 2 shows the fully assembled pump 440 in perspective view. FIG. 3 shows the pump in exploded view. FIG. 4 shows an impeller chamber subassembly 473 of the pump 400 in an exploded and partial cross-sectional view. FIG. 5 shows the pump 400 in a longitudinal cross-sectional view. FIG. 6 shows the pump 400 in a lateral cross-sectional view. FIGS. 7-12 show stator subassemblies 471/472 of the pump 400 and components thereof in various stages of assembly.

Components of the pump 400 are described below in a hierarchical order intended to facilitate understanding of the structural and functional relationships between the components. However, this order of description is not necessarily the same as the order in which the components appear in the drawings. Thus, FIGS. 2-12 will not be described in strict sequence below. Instead, as aspects of the pump are described, certain figures that are thought to be most helpful to understanding the particular aspect under discussion will be called out, even if that requires moving back and forth between the drawings out of order.

As shown in FIGS. 2 and 3, the pump 400 comprises a number of subassemblies, including a first stator subassembly 471, a second stator subassembly 472, an impeller chamber subassembly 473, an inlet subassembly 475, and an outlet subassembly 476. Each of these subassemblies will be described in greater detail below.

As shown in FIGS. 2 and 3 the first and second stator subassemblies 471 and 472 are positioned on diametrically opposite lateral sides of the impeller chamber. These stator subassemblies 471 and 472 comprise frames 411a and 411b, respectively, which make up part of the housing 410 and which also support other components of the assemblies 471 and 472. The stator subassemblies 471 and 472 also comprise first and second stator portions 420a and 420b held by the frames 411a and 411b, respectively. In addition, the first and second stator subassemblies 471 and 472 comprise the PCBs 425a and 425b held by the frames 411a and 411b, respectively, which make up a split PCA, such as the split PCA described in the U.S. patent application Ser. No. 17/976,406 entitled “AXIAL PUMP WITH SPLIT PRINTED CIRCUIT BOARD ASSEMBLY (PCA)” and filed on Oct. 28 2022, the entire contents of which is incorporated herein by reference. The stator portions 420a/420b are provided electrical current from the split PCA and, in response, generate the magnetic fields which drive the rotation of the rotor. The stator subassemblies 471 and 472 will be described in greater detail below with reference to FIGS. 6-12 following the description of the other aspects of the pump 400.

As shown in FIGS. 3 and 4, the impeller chamber subassembly 473 comprises an impeller chamber 433 and an impeller/rotor subassembly 474 housed (at least partially) within the impeller chamber 433. The impeller chamber 433 comprises a front portion 433a and a rear portion 433b. The impeller chamber front portion 433a comprises a bore 467 and the rear portion 433b comprises a bore 450. As suggested by the arrows in FIG. 4 when the impeller chamber subassembly 473 is assembled the front portion 433a and rear portion 444b are coupled together with the impeller/rotor subassembly 474 positioned partially inside the bore 467 and partially inside the bore 450. As shown in FIG. 3, the impeller chamber front portion 433a comprises engagement portion 438, which defines a rear opening of the bore 467. As shown in FIG. 6, the impeller chamber rear portion 433b comprises an engagement portion 455 configured to engage with (e.g., be received within) the engagement portion 438 of the front portion 433a to couple the front portion 433a and rear portion 433b together. The engagement portion 455 encircles and defines the bore 450.

As shown in FIG. 4, the impeller/rotor subassembly 474 comprises an impeller 440 coupled to a rotor 442, which is in turn coupled to a shaft 443. The impeller 440 comprises an impeller body 445, blades 441 protruding radially from the impeller body 445 and spiraling axially and circumferentially along and around the outer surface of impeller body 445. The shaft 443 comprises a front end 443a and a rear end 443b.

As shown in FIG. 5, the rotor 442 comprises a bearing tower which includes a bearing tower shaft 461, a front bearing housing 449 attached to a front end of the bearing tower shaft 461, and a rear bearing housing 448 attached to a rear end of the bearing tower shaft 461. The rotor 442 also comprises magnets 446 which are distributed around the bearing tower shaft 461 and fixedly coupled to the bearing tower so as to move together with the bearing tower. The shaft 443 extends through an interior axial boar of the bearing tower shaft 461, as well as through a central bore 469c of the front bearing housing 449 and central openings in the front and rear radial bearings 447a and 447c and rear thrust bearing 447b. The bearing housings 448 and 449 each house bearings 447 that rotatably coupled the rotor 442 to the shaft 443. Specifically, as shown in FIG. 5, the front bearing housing 449 contains front radial bearings 447a that bear radially against the shaft 443, whereas the rear bearing housing 448 contains rear radial bearings 447b that bear radially against the shaft 443 and rear thrust bearings 447c that bear axially against a flange of the shaft 443. The front and rear bearing housings 449 and 448 may also engage with the magnets 446 to help secure the magnets 446 on the shaft 461. A spring clip retainer 465 may be inserted into the rear bearing housing 448 behind the thrust bearing 447b to retain the thrust bearing 447b in the housing 448. A clip 468 may be attached to the shaft 443 forward of the front bearing housing 449, and a spring may be disposed between the clip 468 and the front radial bearing 474c to hold the front radial bearings 447 in the bearing housing 449.

As show in FIG. 5, the rotor 442 (with the shaft 443 coupled thereto) is received within the impeller 440 and the impeller 440 is attached thereto (e.g., via press fitting, adhesives, or other means) to form the impeller/rotor subassembly 447. For example, the front bearing housing 449 may engage with an engagement portion 445a inside a central internal cavity of the impeller body 445 to attach the rotor 442 to the impeller 440. An example of an impeller/rotor subassembly which may be used as the impeller/rotor subassembly 474, as well as an example method of manufacturing such a subassembly, is described in U.S. patent application Ser. No. 18/930,262, the entire contents of which are incorporated herein by reference.

Once the impeller/rotor subassembly 474 is assembled, it may be inserted into the conduit 430 and the shaft 443 may be coupled to the conduit 430. Thus, as the impeller 440 rotates about the shaft 443 it also rotates relative to the conduit 430. As shown in FIGS. 4 and 5, when the impeller chamber subassembly 473 is assembled, the impeller 440 is contained within the impeller chamber 433, with a front end 443 of the shaft 443 thereof coupled to the front portion 433a of the impeller chamber 433 and a rear end 443b of the shaft 443 coupled to the rear portion 433b of the impeller chamber 433. More specifically, a front end 443a of the shaft 443 of the impeller 440 is inserted into a hub 484 in a front support 444, as shown FIG. 5. The front support 444 is coupled to the walls of the impeller chamber 433. Thus, when the front end 443a is engaged by the front support 444, the front support 444 supports the shaft 443 relative to the impeller chamber 433. Similarly, the rear end 443b of the shaft 443 is inserted into and engaged by a rear support 451 of the rear portion 433b of the impeller chamber, as shown in FIG. 5. In particular, an adjustment mechanism 436 is used to couple the shaft 443 to the rear support 451. The adjustment mechanism 436 comprises a nut 436a, a set screw 436b of the shaft 443, and a socket 436c in the end of the shaft 443. The nut 436a is attached to a nut holding portion 453 of the rear support 451 and receives the set screw 436b such that rotation of the shaft 443 relative to nut 436a causes shaft 443 to translate relative to rear support 451. Socket 436c receives a tool to allow rotation of the shaft 443 in this manner.

As shown in FIGS. 4 and 5, the rear support 451 comprises a cylinder 452 encircling the bore 450, a nut holding portion 453 coupled to one end of the cylinder 452, and attachment portions 454 that extend radially from the cylinder 452 to couple the cylinder 452 to the engagement portion 455. Although not visible in the figures, the attachment portions 454 are arranged so as to not block the flow of liquid through the chamber 433, with the liquid flowing through the space between the engagement portion 455 and the cylinder 452 and around the attachment portions 454.

The impeller chamber 433 is also coupled to various support structures and/or comprises various surfaces that form part of the housing 410 and which facilitate joining of the other subassemblies together. For example, as shown in FIG. 4, the rear portion 433b comprises fastener holders 459 with holes 458 to receive fasteners 477. As shown in FIGS. 3 and 4 the front portion 433a comprises holes 437, and when the front portion 433a and rear portion 433b are coupled together the holes 437 align with the holes 458. Thus, as shown in FIG. 3 a fastener 477 is inserted through the holes 437 and 458 to secures the front portion 433a and rear portion 433b in the coupled state. In addition, as shown in FIG. 4, the rear portion 433b also comprises holes 457, which receive fasteners 479b and 479c, as shown in FIG. 3. Similarly, the front portion 433a comprises holes 485, as shown in FIG. 4, to receive fasteners 479a and 479d, as shown in FIG. 3. These fasteners 479a-d are used to couple the various subassemblies together, as will be described below. In some examples, the front portion 433a may also comprise holes 481, which may be used to fill the pump 400 with epoxy after assembly to make the pump 400 water resistant and also to aid with transfer of heat from pump 400 components into the coolant by removing air gaps. Furthermore, the impeller chamber 433 is coupled to housing portions 410i, 410j, 410k, and 410L.

The inlet subassembly 475 comprises an inlet end wall portion 410a and lateral wall portions 410b and 410c coupled to the inlet end wall portion 410a. The inlet subassembly 475 also comprises the inlet 431 and vibration isolators 466, which are formed in or coupled to the inlet end wall portion 410a. The outlet subassembly 476 comprises an outlet end wall portion 410f and lateral wall portions 410e and 410g coupled to the outlet end wall portion 410f. The outlet subassembly 476 also comprises the outlet 432 and vibration isolators 466, formed in and/or coupled to the outlet end wall portion 410f. In the illustrated example, the inlet 431 and outlet 432 comprise hose barb couplings. In other examples, other types of liquid couplings may be substituted for the hose barb couplings. The pump 400 may be coupled to another device (e.g., a chassis of a computing device that the pump 400 is disposed within) via the vibration isolators 459. The vibration isolators 459 may be rubber, silicon, or another compliant material that helps to absorb vibrations generated by the pump 400 and prevent (or reduce) the transmission of these vibrations to the device in which the pump 400 is disposed. As shown in FIG. 3, the outlet 432 comprises an engagement portion 487. This engagement portion 487 is configured to engage with an engagement portion 456 of the impeller chamber rear portion 433b, as shown in FIG. 5. As shown in FIG. 5, pump 400 also may comprise an outlet guide vane (OGV) 434 which extends into the bore of the engagement portion 487 and the outlet 432 of the outlet subassembly 476. The OGV 434 comprises fins 434a, which guide the flows of liquid as they exit the impeller chamber 433 and enter the outlet 432. This OGV 434 may help to straighten out the flows, removing or reducing some of the circumferential motion of the liquid flows, which is introduced by the rotation of the impeller 440, so that the fluid moves predominantly (or, in some cases, only) axially upon exiting outlet 432.

As shown in FIG. 3, the inlet and outlet subassemblies 475 and 476 may be positioned on opposite axial sides of the impeller chamber subassembly 473. Thus, during assembly of the pump 400 the inlet and outlet subassemblies 475 and 476 may be positioned as shown in FIG. 3 and then moved towards one another (along directions indicated by arrows 404 and 405) until the inlet 431 is fluidically coupled with one side of the impeller chamber 433 and the outlet 432 is fluidically coupled with the other side of the impeller chamber 433. In some examples, this assembly step may occur after the two stator subassemblies 471 and 472 have been assembled onto the impeller chamber subassembly 473. Once the inlet 431, outlet 432, and impeller chamber 433 are coupled together, they form the conduit 430 through which liquid coolant may flow along a central axis 439 thereof.

Turning now to FIGS. 6-12, the stator subassemblies 471 and 472 will be described in greater detail. As shown in FIG. 6, stator subassembly 471 comprises a stator frame 411a, top and bottom stator core portions 421a-1 and 421a-2, and wire winding 424a which is wound around the stator core portions 421a-1 and 421a-2. Similarly, subassembly 472 comprises a stator frame 411b, top and bottom stator core portions 421b-1 and 421b-2, and wire winding 424b which is wound around the stator core portions 421b-1 and 421b-2. The stator core portions 421a-1, 421a-2, 421b-1, and 421b-2 may be referred to as stator core portions 421 when it is not necessary to distinguish one from the other. Each of the stator core portions 421 comprises a vertically extending base portion 426 and a stator tooth 422 extending horizontally from the base portion 426. The base portion 426 is the part of the stator core portion 421 around which the wire windings 424a/424b are wound. The stator teeth 422 extend laterally from the base portions 426 towards the impeller chamber 433. Specifically, each stator tooth 422 may comprise a proximal portion 422p which is joined to the base portion 426 and which extends horizontally from the base portion 426, passing over or under the winding 424a or 424b. The proximal portion 422d may extend past the edge of the winding 424a or 424b. In some examples, the proximal portion 422d is rectangular in cross-sectional profile. Each stator tooth 422 further comprises a distal portion 422d which is joined with the end of the proximal portion 422p and positioned adjacent the chamber 433.

The distal ends 422d of the stator teeth 422 may have shapes configured to produced desired magnetic field properties. In the illustrated examples, the distal ends 422d have the general shapes of curvilinear triangles with blunted (cut) corners. In some examples, the distal ends 422d of the stator teeth 422 may have cross-sectional shapes that are different from those shown in FIG. 6.

In some examples, the distal ends 422d have vertically protruding sections 422v/422v′ which protrude downward below, or upward above, the proximal portions 422p. In particular, as shown in FIG. 6, each top stator tooth 422 has a downward protruding section 422v and each bottom stator tooth 422 has an upward protruding section 422v′. These vertically protruding sections 422v/422v′ horizontally cover portions of the windings 424a or 424b, as shown in FIG. 6. Specifically, in some examples, the vertically protruding sections 422v/422v′ horizontally cover at least 50% of the height “h” of the windings 424a and 424b, wherein the height “h” of the windings 424a/424b refers to their extent along the winding axis thereof (the winding axis being coaxial with the central axis 415′ of the bobbin column 412). In other words, in some examples, an opening that is defined between an upward protruding section 422v and a downward protruding section 422v′, has an opening width “X” (see FIG. 6) that is less than half the heigh “h”.

In the example illustrated in FIG. 6, some of the distal ends 422d have a different cross-sectional profile than others of the distal ends 422d. In particular, the downward protruding sections 422v of the stator core portions 421a-1 and 421b-1 have different lengths than one another, and similarly the upward protruding sections 422v′ of the stator core portions 421a-2 and 421b-2 have different lengths than one another. In other examples (not illustrated), the distal ends 422d of the stator teeth 422 could all have shapes that are identical to one another.

As shown in FIGS. 6-8, the stator frame 411a comprises a top portion 410d, which comprises a horizontal wall forming part of the top face of the housing 410, and a bottom portion 410d′, which comprises a horizontal wall forming part of the bottom face of the housing 410. The top portion 410d and the bottom portion 410d′ are vertically aligned and spaced apart from one another. The top portion 410d includes a top arm 413a-1 which protrudes laterally from the remainder of the top portion 410d, and the bottom portion 410d′ includes a bottom arm 413a-2 which protrudes laterally from the remainder of the bottom portion 410d′ and which is disposed opposite from the top arm 413a-1. The top and bottom arms 413a-1 and 413a-2 hold therebetween the PCB 425a. In some examples, the top and bottom arms 413a-1 and 413a-2 include grooves 416 into which opposite edges of the PCB 425a may be inserted to hold the PCB 425a.

As shown in FIGS. 6-8, the stator frame 411a further comprises a bobbin column 412 which is connected to and extends vertically between the top portion 410d and the bottom portion 410d′. The bobbin column 412 is hollow with a bore 415 extending vertically therethrough. The bobbin column 412 is configured to receive a wire wound circumferentially around the exterior thereof to form winding 424a, with an axis of winding being coaxial with the central axis 415′ of the bore 415.

The frame 411a also has winding stops 417 arranged adjacent to two lateral outer surfaces of the bobbin column 412. Two of the stops 417 are provided on or adjacent the top portion 410d while two other stops 417 are provided on or adjacent the bottom portion 410d'. The stops 417 are configured to prevent the winding 424a from spreading two far axially upward or downward along the bobbin column 412. In particular, when the stator core portions 421 are fully installed (as will be described below), the stator teeth 422 thereof are supposed to be positioned adjacent to, and extend across, a top edge 412′ or a bottom edge 412′′ of a front wall of the bobbin column 412. However, if the winding 424a is allowed to spread axially up and down the full length of the bobbin column 412, then the windings 424a may interfere with the stator teeth 422, preventing them from being positioned sufficiently close to the top edge 412′ or bottom edge 412′′. This mispositioning of the stator core portion 421 can result in the magnetic fields which are generated thereby not having the desired pattern or strength. Thus, to avoid the windings 424a from interfering with the stator teeth 422 and potentially preventing the stator core portion 421 from being correctly positioned, the stops 417 are provided to constrain the wire during the winding process to remain within certain bounds, which are narrower than the full length of the bobbin column 412.

The frame 411a also comprises supports 414. The supports 414 protrude from the top and bottom portions 410d and 410d′ towards the chamber 433. The supports 414 are positioned adjacent to, and provide some support to, the stator core portions 421. The supports 414 may also interact with other portions of the housing 410 to aid in securing the portions together and providing stability and strength to the overall housing 410. The supports 414 may also assist in supporting PCB portions or other devices, as will be described below.

As shown in FIGS. 3 and 6, in this example the frame 411b is substantially similar to the frame 411a except for being oriented in opposite directions across the central axis 139 when the pump 400 is assembled. Thus, the structures shown in FIGS. 7 and 8 for the frame 411a would also be present in the frame 411b in substantially similar arrangements, albeit some of these structures of the frame 411b may be assigned different reference numbers herein than the similar structures in the frame 411a. In particular, the frame 411b comprises a top portion 410h and a bottom portion 410h′ substantially similar to the top and bottom portions 410d and 410d′ of frame 411a. The top and bottom portions 410h and 410h′ comprise arms 413b-1 and 413b-2 to hold PBC 425b, substantially similar to arms 413a-1 and 413a-2 of frame 411a. The frame 411b also includes a bobbin column 412, supports 414, and stops 417 which are substantially similar to those structures as already described above with respect to the frame 411a. In some examples, the frames 411a and 411b are identical to one another and are each symmetrical about a centerline thereof, which allows a single frame design to be interchangeably used as either one of the frames 411a and 411b, e.g., the frame 411a could be turned into the frame 411b by flipping it 180 degrees about its centerline, or vice versa.

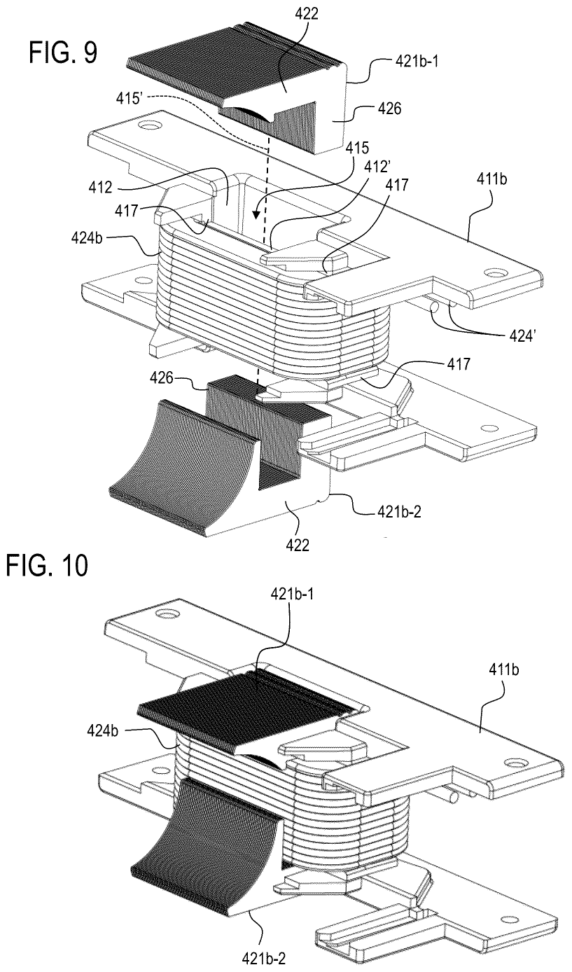

The stator subassemblies 471 and 472 may be manufactured in the following manner. First, the frames 411a and 411b are provided in the state without the stator core portions 421 coupled thereto, as shown in FIGS. 7 and 8. Then, the frame 411a has a wire wound circumferentially around the outer surface of its respective bobbin column 412 multiple times to form a winding 424a thereon. The frame 411b is similarly wound with a wire to form winding 423b thereon. This results in a subassembly comprising the frame 411b with the winding 424b formed thereon, as shown in FIG. 9, and also a similar subassembly comprising the frame 411a with the winding 424a formed thereof. As shown in FIG. 9, the winding 424b is constrained by the stops 417, which prevent the winding 424b from extending too far up or down along the bobbin 412, leaving room for the stator core portions 421. The same is true for the winding 424a. Furthermore, each of the windings 424a/424b has loose wire ends 424′ extending therefrom, which will be used for providing electricity to the winding 424a/424b.

Next, the stator core portions 421 are positioned above and below the frames 411a and 411b, with their respective vertically extending base portions 426 aligned with the central axis 415′ of the bore 415 of the bobbin column 412. More specifically, as shown in FIG. 9, top stator core portion 421b-1 is positioned above frame 411b and bottom stator core portion 421b-2 is positioned below the frame 411b. Similarly, the top stator core portion 421a-1 is positioned above the frame 411a and the bottom stator core portion 421a-b is positioned below the frame 411a.

Next, the stator core portions 421 are translated along axis 415′ until the base portions 426 thereof are inserted into the bore 415 of the bobbin column 412. For example, the top stator core portion 421b-1 is moved downwards along the axis 415′ until its base portion 426 is inserted into the bore 415 of frame 411b via a top opening of the bore 415, and the bottom stator core portion 421b-2 may be moved upwards along the axis 415′ until its base portion 426 is inserted into the bore 415 via a bottom opening thereof. The stator core portions 421a-1 and 421b-1 are inserted into the bobbin 412 of frame 411a in the same manner. The motion of the stator core portions 421 along the axis 415′ is continued so as to advance their base portions 426 farther through the bore 415 until they reach their installed positions, which are shown in FIGS. 6 and 10. In some examples, in the installed positions of the stator core portions 421, their respective base portions 426 are in contact with one another, as shown in FIG. 6. In other examples, there may be a slight gap between the base portion 426. Furthermore, in the installed positions, the stator teeth 422 of each stator core portion 421 extends horizontally across (above or below) the winding 424a/424b, with the stator tooth 422 adjacent a top or bottom edge 412′ or 412″ of the bobbin column 412.

Once in the installed positions, the stator core portions 421 may be attached to the frame 411a or 411b. In some examples, the attachment may comprise a fritting fitting, i.e., friction between the base portion 426 and the interior walls of the bobbin column 412 may be sufficient to securely attach the stator core portions 421 to the frame 411a or 411b. In some examples, other attachments mechanisms may be used, in addition to or in lieu of the friction fitting, such as adhesive (e.g., epoxy), mechanical fasteners (e.g., a clip extending across the top or bottom of the stator core portion 421), or other attachment mechanisms.

Because these vertically protruding sections 422v/422v′ horizontally cover portions they windings 424a/424b and leave an narrow opening therebetween, they would tend to interfere with a wire being wound around the base portion 426, making winding the wire directly around the stator core portions 421 challenging. However, because the windings 424a and 424b are created first on the bobbin columns 412 and then the stator core portions 412 are later inserted into the bobbin columns 412, the vertically protruding portions of the stator teeth 422 do not interfere with winding the wire or otherwise pose a problem to assembly.

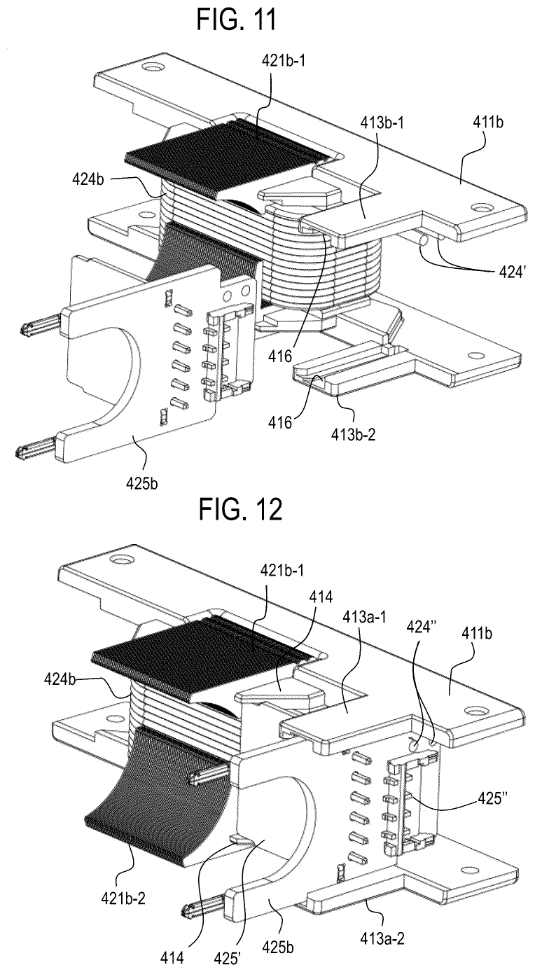

Next, the PCB 425b may be positioned such that the top and bottom edges thereof are aligned with the grooves 416 of the arms 413b-1 and 413b-2, as shown in FIG. 11. The PCB 425a is positioned similarly with respect to the arms 413a-1 and 413a-2 of the frame 411a.

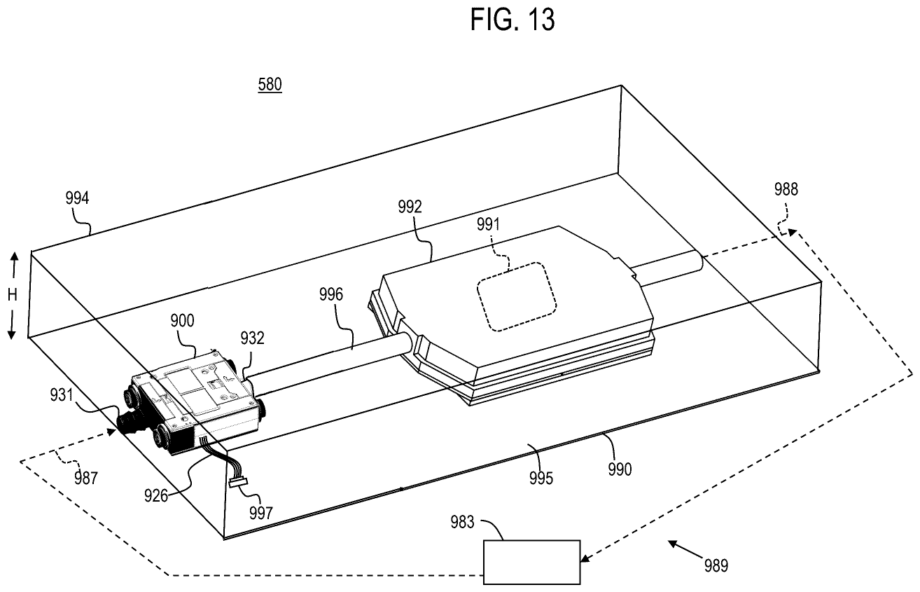

The PCB 425b may then be translated laterally with the top and bottom edges thereof being inserted into, and sliding along, the grooves 416 of the arms 413b-1 and 413b-2, until reaching a fully installed position as illustrated in FIG. 12. The PCB 425a is inserted in the frame 411a in the same manner. In some examples, the PCBs 425a/425b may be held in the installed state merely by friction and by the electrical connection to the wire ends 424′. In other examples, adhesives or other fasteners may be used to further secure the PCBs 425a/425b to the frames 411a/411b. As shown in FIG. 12, in some examples, one or both of the PCBs 425a and 425b may include an extension board 425′ which extends perpendicularly from the PCB 425a or 425b and which is electrically coupled thereto, e.g., via a board-to-board connection. The extension board 425′ may provide more surface area on which electrical components can be disposed, thereby increasing the capabilities of the split PCA. Moreover, the extension board 425′ may extend into a space which would have otherwise been empty, and therefore the extension board 425′ may be added without increasing the overall size of the pump 400. In some examples, the distal end of the extension board 425′ may be engaged with the supports 414 of the frame 411a or 411b, with the supports 414 helping to support and secure the extension board 425′. In some examples, the supports 414 comprise notches into which the edges of the extension board extend to secure the extension board 425′ to the supports 414 by friction engagement. In some examples, adhesives, mechanical fasteners, or other fastening mechanisms may be used to secure the extension board 425′ to the supports 414 in addition to or in lie of the friction fitting.

In addition, the loose wire ends 424′ of the wire which forms the winding 424b may be electrically connected to the PCB 425b via wire attachment points 424'', as shown in FIGS. 11 and 12. In this manner, the winding 424b is electrically connected to the PCB 452b, such that the PCBb can supply electrical driving signals to the winding 424b to generate magnetic fields. The winding 424a is electrically connected to the PCB 425a in the same manner. The wire attachment points 424′′ of the PCB 425a/425b may be any desired form of electrical termination, such as plated through-holes into which the loose ends 424′ are inserted and soldered, electrical contact pads to which the wire ends 424′ are soldered, jacks, lugs, screw terminations, or any other form of electrical termination. This completes the assembly of the stator subassemblies 471 and 472.

Once the stator subassemblies 471 and 472 are assembled, they may be assembled together with the other subassemblies of the pump 440 in the following manner. The first and second stator subassemblies 471 and 472 are positioned on opposite lateral sides of the impeller chamber subassembly 473, similarly as shown in the exploded view of FIG. 3. Next, the stator subassemblies 471 and 472 may be moved laterally towards one another and towards the impeller chamber subassembly 473 positioned therebetween (i.e., along the directions 402 and 403 shown in FIG. 3) until the stator subassemblies 471 and 472 are positioned adjacent to, and partially surrounding, the impeller chamber subassembly 473. In this state, the stator core portions 420a and 420b are positioned adjacent to and radially surround the impeller chamber 433, except for small regions at the top and bottom of the impeller chamber 433, which are not surrounded, as shown in FIGS. 2 and 6. The frames 411a and 411b of the first and second stator subassemblies 471 and 472 are coupled to the impeller chamber subassembly 473 in this position, for example via engagement of fasteners 479a-d with the holes 478a-d. Moreover, as the stator subassemblies 471 and 472 are brought together around the chamber 433, the PCBs 425a and 425b become electrically coupled together by engagement of electrically connectors thereof which extend over and/or under the chamber 433, as suggested in FIG. 3 and as explained in U.S. patent application Ser. No. 17/976,406. The input assembly 475 and output assembly 476 may then be coupled to the impeller chamber subassembly 473 and the two stator subassemblies 471 and 472, with fasteners 479a-d engaging with holes 478a′-d′.

In some examples, prior to, during, or after the assembly of the stator subassemblies 471 and 472, one of the PCBs 425a/425b may be electrically connected to a power cable 426 which supplies electrical power to the pump 400. This cable 426 is shown coupled to PCB 425b in FIG. 3, but may be coupled to the other PCB 425a in other examples. In FIG. 3, the cable is shown as being permanently coupled to the PCB 425b via soldered connection, but in some examples, the cable may be removably coupled to the PCB 425a or 425b via an electrical connector, such as the electrical connector 425′′ illustrated in FIG. 12.

As shown in FIGS. 2 and 3, the pump 400 comprises a housing 410. The housing 410 has a top face, a bottom face, and four side walls extending between and perpendicular to the top and bottom faces. The housing 410 may be made up of multiple distinct portions that are joined together. Specifically, the various subassemblies described above may comprise various structures which together form portions of the housing 410.

The top face of the housing 410 is formed from the top portions 410d, 410h, 410i, 410j, 410k, and 410L. The top portions 410d and 410h are part of the first and second stator subassembly 471 and 472, whereas the top housing portions 410i, 410j, 410k, and 410L are coupled to the conduit 430 and are part of the impeller chamber subassembly 473.

Note that the top face of the housing 410 is not necessarily uniformly flat and does not necessarily fully cover all of the pump 400. For example, a top of the stator portions 420a and 420b may be exposed and approximately coplanar with the top face of the housing 410 (this may allow the height dimension of the pump 400 to be reduced to the absolute minimum possible for a given size of stator 420). Furthermore, portions of the chamber 433 may also be exposed. In some examples, the exposed portions of the stator portions 420a and 420b and chamber 433 may also be considered as being part of the top face of the housing 410. In some examples, epoxy or other filler/sealant may be added to cover these exposed portions, in which case the epoxy or other material may also form part of the top face of the housing 410.

The bottom face of the housing 410 may be similarly constructed as the top face and thus duplicative illustration and description of the bottom face portions is omitted. In particular, in some examples, for each of the top portions 410d, 410h, 410i-410L, there is a corresponding bottom portion which is disposed opposite therefrom and which has a similar configuration as the corresponding top portion (these bottom portions are generally not labeled in the figures, with the exception of bottom portion 410d′ and 410h′).

The perimeter side walls of the housing 410 are formed from the inlet end wall portion 410a, lateral wall portions 410b and 410c, outlet end wall portion 410f, and lateral wall portions 410g and 410e. The inlet end wall portion 410a and lateral wall portions 410b and 410c are part of the inlet subassembly 475. The outlet end wall portion 410f and lateral wall portions 410g and 410e are part of the outlet subassembly 475.

Some of the housing portions may include holes 478 (e.g., 478a, 478b, etc.) (only some are labeled) that are arranged to receive a corresponding fastener 479 (e.g., 479a, 479b, etc.) to couple the subassemblies together. For example, in some implementations including the one illustrated in FIG. 3, the impeller chamber subassembly 473 comprises fasteners 479a, 479b, 479c, and 479d. These fasteners may comprise pins (e.g., spring-biased push pins), screws, bolts, pegs, studs, or any other fasteners. The fasteners 479a, 479b, 479c, and 479d may be inserted into corresponding holes 478a, 478a′, 478b, 478b', 478c, 478c', 478d, and 478d′ of one more the subassemblies to secure the respective subassemblies together. A single fastener 479 may be inserted through two corresponding holes 478 of two different subassemblies. For example, the fastener labeled 479a in FIG. 3 may be inserted into the two holes labeled 478a and 478a′ which are part of the stator subassembly 471 and the inlet subassembly 475, the fastener labeled 479b may be inserted into the two holes labeled 478b and 478b′ which are part of the stator subassembly 471 and the outlet subassembly 476, the fastener labeled 479c may be inserted into the two holes labeled 478c and 478c′ which are part of the stator subassembly 472 and the outlet subassembly 476, and the fastener labeled 479d may be inserted into the two holes labeled 478d and 478d′ which are part of the stator subassembly 472 and the inlet subassembly 475. Note that only the fasteners 479 and corresponding holes 478 on a top side of the housing 410 are labeled in FIG. 3, but it should be understood that similar holes and fasteners are present on the bottom side of the housing 410 and may be joined in the same fashion.

FIG. 13 comprises a schematic diagram illustrating an example system 980 and electronic device 990. The system 980 comprises the electronic device 990 and a liquid cooling loop 989 coupled to the electronic device 990. The system may also comprise additional electronic devices (not illustrated). For example the system 980 may comprise a rack or plurality of racks of electronic devices. The electronic device 990 is illustrated in a state of being installed in the system 980 for convenience of description, but it should be understood that the electronic device 990 may be provided separate from the system 980.

The liquid cooling loop 989 comprises the pump 900 (described below), one or more coolant supply lines 987, one or more coolant return lines 988, and one or more additional cooling loop components 983 such as a heat exchanger, rack-, row-, or datacenter-level coolant distribution unit(s), a chiller, or other cooling components that would be familiar to those of ordinary skill in the art.

The electronic device 990 comprises a PCB 995, such as a baseboard or motherboard of a computing device, and a chassis 994 supporting and housing the PCB 995. The PCB 995 comprises an electrical component 991, such as a processor, power supply unit, memory device, hardware accelerator, or any other electrical component. The electronic device 990 further comprises a cold plate 992 thermally coupled to the electrical component 991.

The electronic device 990 further comprises a pump 900 disposed with in the chassis 994. The pump 900 may be any of the pumps described above, such as the pump 100 and the pump 400. The pump 900 is fluidically coupled with the cold plate 992 via coolant line 996. The pump 900 is electrically connected to the PCB 995 via wires/cable connected to connector 997 of the PCB 995. Thus, the PCB 995 can supply power to and/or communicate with the pump 900. The pump 900 comprises an inlet 931 that may be coupled to the liquid coolant supply line 987 of the liquid cooling loop 989 of the system 980, which supplies liquid coolant to the pump 900. An outlet 932 of the pump 900 is coupled to the coolant line 996. An outlet of the cold plate 992 may be coupled to a liquid coolant return line 988 of the liquid cooling loop, which returns liquid coolant to the remainder of the loop for eventual cooling (e.g., at a heat exchanger). Thus, when the electronic device 990 is installed in the system 980 and fluidically coupled into the liquid cooling loop 989 thereof, liquid coolant from the loop 989 can flow through the pump 900 and cold plate 992. In particular, the pump 900 may be configured to cause (or at least contribute to) the flowing of the liquid coolant through the cold plate 992 to cool the electrical component 991.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An axial pump for delivering liquid coolant to cool an electronic device, comprising:
a conduit defining a flow path from an inlet of the conduit to an outlet of the conduit;
an impeller in the conduit;
a shaft disposed in and coupled to the conduit;
a rotor disposed in a hollow interior of the impeller and rotatably coupled to the shaft, the impeller configured to rotate with the rotor about an axis of rotation extending parallel to the flow path;
a stator configured to drive rotation of the rotor about the shaft and comprising a first stator subassembly and a second stator subassembly disposed on diametrically opposite lateral sides of the conduit, wherein each of the first and second stator subassemblies comprises:
a frame comprising a bobbin column comprising a bore extending therethrough;
a winding wound around the bobbin column;
a top stator core portion inserted into the bore of the bobbin column via a top opening in the bore;
a bottom stator core portion inserted into the bore of the bobbin column via a bottom opening in the bore.

2. The axial pump of claim 1,
wherein, for each of the first and second stator subassemblies, the frame comprises a top wall and a bottom wall, wherein the bobbin column extends between the top and bottom walls.

3. The axial pump of claim 2, further comprising:
a housing, wherein, for each of the first and second stator subassemblies, the top wall and the bottom wall of the frame form part of the housing.

4. The axial pump of claim 2, further comprising:
a split PCA comprising two distinct PCBs electrically connected together;
wherein, for each of the first and second stator subassemblies, the frame further comprises a top arm and a bottom arm protruding laterally from the top wall and the bottom wall, respectively, and holding one of the PCBs therebetween.

5. The axial pump of claim 1,
wherein, for each of the first and second stator subassemblies, the frame comprises stops configured to prevent the winding from extending along a full length of the bobbin column.

6. The axial pump of claim 1,
wherein, for each of the first and second stator subassemblies:
the top stator core portion comprises a first base portion extending vertically and inserted into the bore of the bobbin column via the top opening in the bore and a first stator tooth extending horizontally from the base portion toward the conduit; and
the bottom stator core portion comprises a second base portion extending vertically and inserted into the bore of the bobbin column via the bottom opening in the bore and a second stator tooth extending horizontally from the base portion toward the conduit.

7. The axial pump of claim 6,
wherein, for each of the first and second stator subassemblies, the first base portion contacts the second base portion within the bore of the bobbin column.

8. The axial pump of claim 6,
wherein, for each of the first and second stator subassemblies, the first base portion and the second base portion are encircled by the winding with walls of the bobbin column positioned between winding and the first base portion and the second base portion.

9. The axial pump of claim 8,
wherein, for each of the first and second stator subassemblies, a distal portion of the first stator tooth comprises a downward protruding section that horizontally covers the winding and a distal portion of the second stator tooth comprises an upward protruding section that horizontally covers the winding.

10. The axial pump of claim 9,
wherein, for each of the first and second stator subassemblies, the downward protruding section and the upward protruding section together horizontally cover at least half of the height of the winding along a winding axis thereof.

11. The axial pump of claim 1,
wherein the top and bottom stator core portions of the first and second stator subassemblies collectively form a stator core having a rectangular cross-sectional profile.

12. An electronic device, comprising:
a printed circuit board (PCB);
an electrical component coupled to the PCB;
a chassis housing the PCB;
a cold plate thermally coupled to the electrical component; and
the axial pump of claim 1 disposed within the chassis, wherein the conduit of the axial pump is fluidically coupled with the cold plate.

13. The electronic device of claim 12,
wherein the electronic device is a server and the electrical component is a processor.

14. A system, comprising:
a plurality of information processing devices, each comprising a chassis, a printed circuit board disposed in the chassis, an electrical component coupled to the PCB, and a cold plate thermally coupled to the electrical component;
a plurality of instances of the axial pump of claim 1, wherein each of the axial pumps is disposed in the chassis of one of the information processing devices, and the respective conduits of the axial pumps are fluidically coupled with the cold plates of the information processing devices, respectively; and
a liquid cooling loop comprising liquid coolant supply lines configured to supply liquid coolant to the axial pumps, liquid coolant return lines configured to return liquid coolant from the pumps, and a heat exchanger configured to cool the liquid coolant.

15. The system of claim 14,
wherein the axial pumps are individually controllable to individually adjust the flow rate of the liquid coolant through the information processing devices.

16. A method of manufacturing an axial pump, comprising:
forming a first stator subassembly by:
providing a first stator frame comprising a first bobbin column with a first bore extending therethrough;
winding a first wire around the first bobbin column to form a first winding thereon, and winding a second wire around the first bobbin column to form a second winding thereon;
after forming the first winding, inserting a first top stator core portion into the first bore via a top opening thereof and inserting a first bottom stator core portion into the first bore via a bottom opening thereof.

17. The method of claim 16, further comprising:
forming a second stator subassembly by:
providing a second stator frame comprising a second bobbin column with a second bore extending therethrough;
winding a second wire around the second bobbin column to form a second winding thereon; and
after forming the second winding, inserting a second top stator core portion into the second bore via a top opening thereof, and inserting a second bottom stator core portion into the second bore via a bottom opening thereof.

18. The method of claim 16, further comprising:
providing a conduit with an impeller/rotor subassembly contained within the conduit with an axis of rotation of the impeller/rotor subassembly being coaxial with a flow direction of liquid through the conduit; and
coupling the first and second stator subassemblies to the conduit with the first stator subassembly on a first lateral side of the conduit and the second stator subassembly on a second lateral side of the conduit diametrically opposite the first stator subassembly.

19. The method of claim 17,
wherein forming the first stator subassembly further comprises attaching a first PCB to the first stator frame;
wherein forming the second stator subassembly further comprises attaching a first PCB to the first stator frame;
wherein coupling the first and second stator subassemblies to the conduit comprises electrically connecting the first and second PCBs together.

20. The method of claim 19,
wherein attaching the first PCB to the first stator frame comprises sliding top and bottom edges of the first PCB into grooves in top and bottom horizontally protruding arms of the first stator frame; and
wherein attaching the second PCB to the second stator frame comprises sliding top and bottom edges of the second PCB into grooves in top and bottom horizontally protruding arms of the second stator frame.
